(19) United States
(12) Patent Application Publication
(10) Pub. No.: US 2024/0327203 A1
(43) Pub. Date: Oct. 3, 2024

(54) METHOD FOR MANUFACTURING A MEMS TRANSDUCER DEVICE WITH THIN MEMBRANE, AND MEMS TRANSDUCER DEVICE

(71) Applicant: STMicroelectronics International N.V., Geneva (CH)

(72) Inventors: Mark Andrew SHAW, Milano (IT); Fabio QUAGLIA, Pizzale (PV) (IT); Domenico GIUSTI, Caponago (IT); Marco FERRERA, Concoerezzo (IT)

(73) Assignee: STMicroelectronics International N.V., Geneva (CH)

(21) Appl. No.: 18/613,746

(22) Filed: Mar. 22, 2024

(30) Foreign Application Priority Data
Mar. 28, 2023 (IT) 102023000005940

(51) Int. Cl. B81B 7/00; B81B 3/00; B81C 1/00; H01L 25/18; H10N 39/00

(52) U.S. Cl. CPC B81B 7/007; B81B 3/007; B81C 1/00301; B81C 1/00658; H01L 25/18; H10N 39/00; B81B 2201/0271; B81B 2203/0127; B81B 2207/012; B81B 2207/096; B81C 2203/0792

(57) ABSTRACT

A method for manufacturing a MEMS device includes forming a first solid body by forming, on a substrate, a layered structure having a thickness of a value comprised between 4 and 10 μm, with the layered structure having a first surface that is uniformly flat or planar throughout the extension thereof that faces the substrate. The method further includes forming, on a second surface of the layered structure opposite to the first surface in a direction, multiple transducer devices. The method then proceeds with coupling the first solid body to a supporting structure, and completely removing the substrate to expose said uniformly flat or planar surface.

### PRIORITY CLAIM

This application claims the priority benefit of Italian Application for Patent No. 10,202,3000005940 filed on Mar. 28, 2023, the content of which is hereby incorporated by reference in its entirety to the maximum extent allowable by law.

### TECHNICAL FIELD

This disclosure relates to a method for manufacturing a MEMS (Micro-Electro-Mechanical System) device, in particular an electroacoustic transducer device, and relates to a MEMS device. In particular, the method enables manufacture of an electroacoustic MEMS device with thin membrane and exposed surface of the membrane that is uniformly planar or flat, without any cavities or depressions or mechanical-reinforcement structures.

### BACKGROUND

As is known, there are today available numerous ultrasonic sensors, which are designed to transmit and receive acoustic waves with frequencies higher than 20 kHz. Typically, an ultrasonic sensor comprises, in addition to a transducer of an electro-acoustic type, a circuitry designed to drive the transducer, as well as to amplify the electrical signals generated by the transducer itself following upon reception of acoustic echo signals. The transducer thus functions both as acoustic emitter and as acoustic receiver, in different time periods.

If by “acoustic stimulation signals” and “acoustic response signals” the acoustic signals (or beams) transmitted by the transducer and the acoustic signals (or beams) that impinge upon the transducer are respectively meant, for example following upon reflection of the acoustic stimulation signals by an obstacle, it is known that there is the desire, for example in the sonographic field, to be able to focus the acoustic stimulation signals. In order to control emission in space of the acoustic stimulation signals, a technique is known that envisages having available a plurality of transducers, each of which emits spherical acoustic waves, and governing said transducers with driving signals appropriately staggered with respect to one another so that the sum of the acoustic stimulation signals generated by the transducers will form an acoustic beam having the desired spatial distribution.

This having been said, in order to increase the performance, in particular regarding amplification of the echo, it is desired for the transducers, typically formed by corresponding MEMS devices arranged in a matrix array, to be located as close as possible to the electronic circuitry, and in particular to the part of electronic circuitry entrusted with amplifying the electrical signals generated by the transducers. However, this conflicts with the high number of transducers (in the region of one thousand) typically used.

In practice, since each transducer is coupled to a respective ASIC (Application-Specific Integrated Circuit), which forms the driving circuit and the receiver associated to the transducer, the thousands of connections present between the transducers and the ASICs connected thereto are to be managed, such management including controlling the delays introduced by the various channels (each channel being understood as being formed by a transducer, the corresponding driving circuit, and the corresponding receiver), as well as the jitter present between the different channels.

This having been said, currently known are manufacturing methods that envisage manufacture of a semiconductor wafer so as to form, in the first wafer, a plurality of transducers, and a second structure manufactured according to a technology known as FOWLP (Fan-Out Wafer-Level Package) so as to integrate, in said second structure, a plurality of ASICs. Next, the first wafer and the FOWLP structure are coupled together so that the transducers are operatively coupled to the corresponding ASICs. This method, however, is characterized by a reduced flexibility, since it envisages adopting a single technology both for the driving circuits and for the receiving circuits. Further, this manufacturing method enables testing of the ASICs only when it is completed. Furthermore, this manufacturing method involves the pitch between the electrical connection pads being the same in the semiconductor wafer and in the FOWLP structure.

United States Patent Application Publication No. 2023/0028024 (incorporated herein by reference) describes a method for manufacturing a device comprising a plurality of electroacoustic modules (transducers). This solution, however, envisages the formation of a plurality of cavities in the membrane, in a position corresponding to each electroacoustic module. During use, when, for example, the device is used for emission of acoustic waves for biomedical applications, these cavities are be filled with an appropriate material, such as a silicone gel to improve the coupling between the body of the patient and the electroacoustic modules. The presence of the cavities may render this operation problematical or, if this operation is not carried out properly, unsatisfactory from the standpoint of complete filling of the cavities.

There is a need in the art for a method for manufacturing a MEMS device, and a corresponding MEMS device, that are designed to overcome at least in part the drawbacks of the prior art.

### SUMMARY

Embodiments herein concern a method for manufacturing a MEMS device and the corresponding MEMS device.

Indeed, disclosed herein is a method for manufacturing a microelectromechanical systems (MEMS) device. The method includes: forming a first solid body that forms a layered structure on a substrate, wherein the layered structure has a first surface that is planar throughout an extension thereof and that faces the substrate; forming a plurality of transducer devices on a second surface of the layered structure that is opposite to the first surface in a direction; coupling the first solid body to a supporting structure; and completely removing the substrate to expose said first surface.

The layered structure may form a membrane, and the plurality of transducer devices may be arranged on the membrane.

The supporting structure may be a TSV (Trough-Silicon Via) wafer.

Forming the first solid body may include forming the supporting structure as a wafer manufactured using FOWLP (Fan-Out Wafer-Level Package) technology having a first side coupled to the first solid body and a second side, opposite to the first side in said direction, coupled to a supporting adhesive tape.

The supporting structure may be formed to include a plurality of integrated circuit dice manufactured using FOWLP technology, each die having a first side coupled to the first solid body and a second side, opposite to the first side in said direction, coupled to a supporting adhesive tape.

The supporting structure may be formed to include a second solid body that includes application specific integrated circuit (ASIC) dice and a redistribution structure. The redistribution structure may be formed to have a first side coupled to the first solid body and a second side, opposite to the first side in said direction, facing the ASIC dice, and wherein conductive paths extend between the first and second sides in electrical connection with the ASIC dice. The supporting structure may be further formed to include a supporting adhesive tape coupled to the second solid body in a position corresponding to said ASIC dice.

The method may further include forming mechanical and electrical coupling structures between the first solid body and the supporting structure.

The method may further include electrically coupling respective coupling structures of said plurality of coupling structures to respective transducer devices of the plurality of transducer devices.

The method may further include forming a stiffening structure around each transducer device of said plurality of transducer devices.

The method may further include forming a stiffening structure around each transducer device, and the coupling structures may be formed to have a respective cross-section, along a cutting plane orthogonal to said direction, having a shape such as to maximize overlap with the stiffening structure around the respective transducer device.

The mechanical and electrical coupling structures may be formed to have a cross-section with a shape chosen from among the group consisting of: hypocycloidal with a number of cusps equal to or greater than three; triangular; and quadrangular.

The method may include removing the supporting adhesive tape after completely removing the substrate.

The method may include, after completely removing the substrate, coupling a second solid body manufactured using FOWLP technology to the TSV wafer.

The second solid body may be formed to comprise ASIC dice and a redistribution structure, the redistribution structure having a first side coupled to the second solid body and a second side, opposite to the first side in said direction, facing the ASIC dice, and with the conductive paths being formed to extend between the first and second sides of the redistribution structure.

The layered structure may have a thickness of a value ranging between 2 and 50 μm.

Also disclosed herein is a microelectromechanical systems (MEMS) device, including: a first solid body including signal-processing circuitry; a second solid body including a membrane having a first side and a second side opposite to one another in a direction, the first side of the membrane facing the first solid body, the first and second solid bodies being fixed with respect to one another; a plurality of transducer devices which extend on the first side of the membrane; and a plurality of coupling elements which extend between the first and second solid bodies and are configured to electrically couple each transducer device to the signal-processing circuitry; wherein said membrane has a thickness that is uniform in said direction; and wherein the second side of the membrane is planar throughout its extension.

The plurality of transducer devices may share a same membrane.

The first and second solid bodies may be coupled together by a through silicon via (TSV) wafer that extends between the first and second solid bodies, and the first solid body may be a wafer manufactured using fan out wafer level packaging (FOWLP) technology.

The MEMS device may be an ultrasonic transducer device.

The MEMS device may be a piezoelectric micromachined ultrasonic transducer (PMUT).

The thickness of the membrane may have a value ranging between 2 and 50 μm.

### BRIEF DESCRIPTION OF THE DRAWINGS

For a better understanding, embodiments are now described, purely by way of non-limiting example, with reference to the attached drawings, wherein:

FIG. 1A is a schematic cross-sectional view of a MEMS device for electroacoustic transductions, in particular a PMUT (Piezoelectric Micromachined Ultrasonic Transducer), according to an embodiment;

FIG. 1B is a schematic perspective view of a portion of the MEMS device of FIG. 1A

FIGS. 2A-2D illustrate sections of electrical coupling elements of the MEMS device of FIG. 1A and FIG. 1B, according to respective embodiments;

FIGS. 3 and 4 illustrate respective embodiments of schemes of mutual arrangement of transducers and electrical coupling elements of the MEMS device of FIG. 1A and FIG. 1B;

FIGS. 5A-5I illustrate steps for manufacturing the MEMS device of FIG. 1A, according an embodiment;

FIG. 6 illustrates a transducer that may be implemented in the MEMS device of FIGS. 1A-1B and 5F-5I;

FIG. 7 is a schematic cross-sectional view of a MEMS device for electroacoustic transductions, in particular a PMUT, according to a further embodiment;

FIGS. 8A-8J illustrate steps for manufacturing the MEMS device of FIG. 7, according to an embodiment; and

FIGS. 9-12 is a schematic cross-sectional view of respective MEMS devices for electroacoustic transductions, in particular PMUTs, according to respective further embodiments.

### DETAILED DESCRIPTION

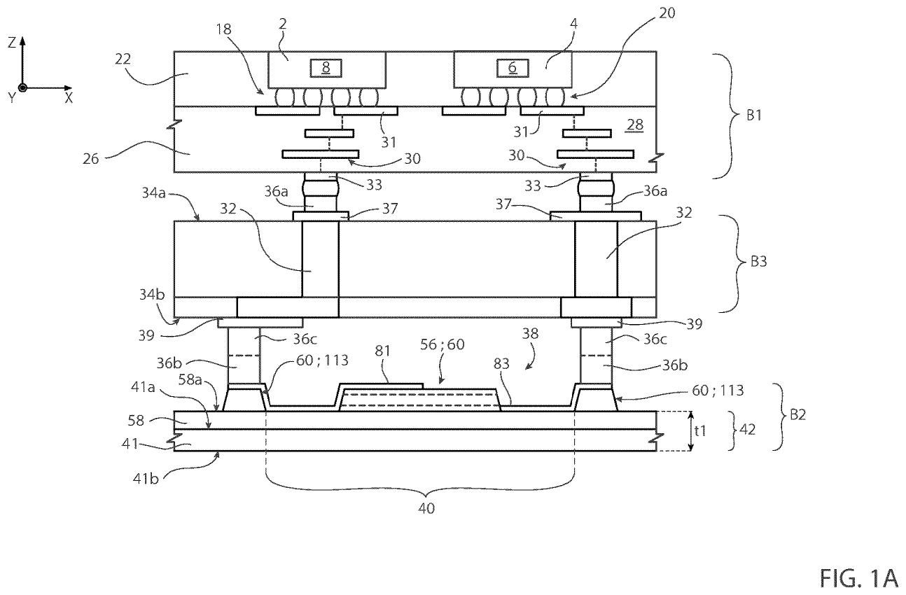

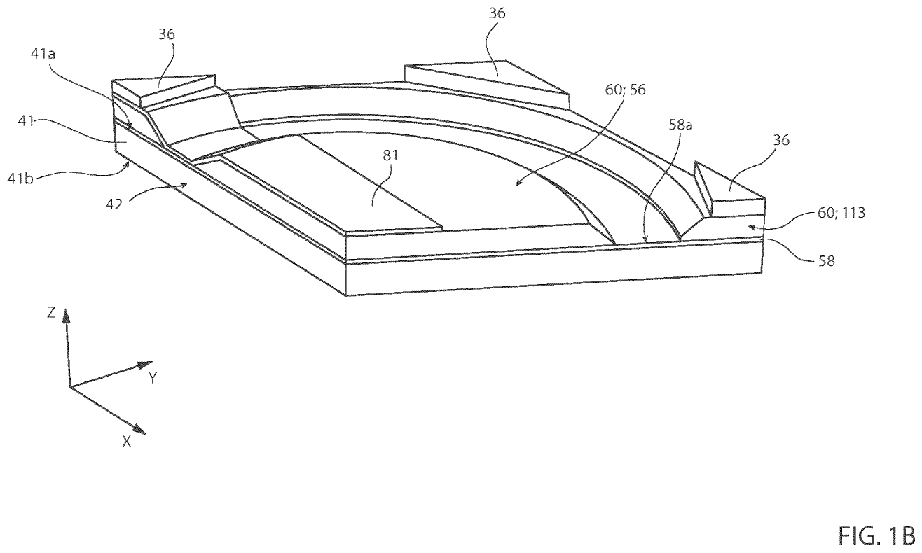

FIG. 1A shows a portion of a MEMS device 1, in particular an electroacoustic device, even more in particular a PMUT (Piezoelectric Micromachined Ultrasonic Transducer), in a triaxial system of mutually orthogonal axes X, Y, Z. The view of FIG. 1A is a cross-sectional view in the plane XZ.

FIG. 1B shows in perspective view a detail of the MEMS device 1 of FIG. 1A (some elements are not present, for simplicity of representation and greater clarity), in the triaxial system XYZ.

Elements in common between FIGS. 1A-1B are designated by the same reference numbers.

With joint reference to FIGS. 1A and 1B, the electroacoustic device 1 comprises a first solid body B1 known as a FOWLP (Fan-Out Wafer-Level Package). The first solid body B1 includes a first die 2 and a second die 4 that house, respectively, a first integrated circuit 6 and a second integrated circuit 8, which are formed, for example, by ASICs. Each one of the first and second integrated circuits 6, 8 comprises a respective transmitting circuit and a respective receiving circuit for respective actuation and detection signals. The transmitting circuit, as described more clearly below, is configured to generate and transmit an actuation signal of an actuator or transducer of the device 1. The receiving circuit, as described more clearly below, is configured to receive and process a signal transduced by a transducer of the device 1. In an embodiment, one of the transmitting circuit and the receiving circuit may be absent.

In each of the first and second integrated circuits 6, 8, the corresponding transmitting and receiving circuits are electrically connected to a corresponding plurality of metal bumps, designated, respectively, by 18 and 20 and also known as microbumps. The bumps metal 18, 20 are electrically connected to metallizations of the corresponding dice 2, 4, for example via respective electrical contact pads.

The first solid body B1 further comprises a coating region 22, which is made, for example, of an epoxy resin and englobes the first and second dice 2, 4.

The first solid body B1 further comprises a redistribution structure 26, which includes a dielectric region 28 that houses a plurality of conductive paths 30 (represented schematically). The redistribution structure 26 is delimited by a first side 26a and a second side 26b, opposite to one another along the axis Z. The conductive paths 30 extend between the first and second sides, reaching the first and second sides. On the sides 26a, 26b are conductive pads 31 (on the side 26a) and conductive pads 33 (on the side 26b). The conductive paths 30 are electrically connected to the conductive pads 31, 33 to form a vertical-connection path (along Z, between the side 26a and the side 26b).

The dielectric region 28 is made, for example, of polyimide (or else, for example, polyamide or a glass-fiber resin). The conductive paths 30 are typically made of metal material, such as copper.

The electroacoustic device 1 further comprises a second solid body B2.

The second solid body B2 comprises a transduction module or structure 38, electrically coupled to the redistribution structure 26. The coupling between the first and second solid bodies B1, B2 is obtained by a third solid body B3, arranged between the first and second solid bodies B1, B2.

The third solid body B3 is, for example, a wafer of semiconductor material that has a plurality of conductive through vias, also known as TSVs (Through Silicon Vias) 32, formed therein. The third solid body B3 has a first surface 34a opposite to a second surface 34b along the axis Z. The conductive through vias 32 extend between the first surface 34a and the second surface 34b and are in electrical connection with respective pads 37, 39 present on the first surface 34a and the second surface 34b, respectively.

The physical and electrical connection between the first solid body B1 and the third solid body B3 is obtained by a plurality of pillars 36a of metal material (for example, gold, copper, tin, or some other metal material), each of which is electrically and physically coupled to a respective pad 33 and to a respective pad 37. The physical and electrical connection between the second solid body B2 and the third solid body B3 is obtained by a further plurality of pillars 36b of metal material (for example gold, or else copper, or else tin, or some other metal material), each of which is electrically and physically coupled to a respective pad 39 and, as described below, to conductive paths of the transduction structure 38, to carry and acquire the actuation and transduced signals to/from the transduction structure 38. Optionally, and as illustrated in the figure, present between the pillars 36b and the pads 39 are further respective pillars 36c, of conductive material, for example metal material.

The transduction structure 38 comprises a structural body 41 having a first surface 41a opposite to a second surface 41b along the axis Z. Extending over the first surface 41a of the structural body 41 is a layer of insulating material 58.

The structural body 41 and the insulating layer 58 have the function of a membrane designed to deflect, and consequently below the layered structure formed by the body 41 and by the layer 58 will be referred to as a “membrane”, designated in the figure by the reference 42. The membrane 42 extends with a thickness t₁ along the axis Z between a top surface 58a, coinciding with the exposed surface of the insulating layer 58, and a bottom surface 41b, coinciding with the bottom surface of the structural body 41. The structural body 41 is made, in particular, and as described more fully hereinafter, of semiconductor material such as silicon. The insulating layer 58 is made, for example, of silicon oxide (SiO₂). In particular, the membrane 42 has, in an area corresponding to the second surface 41b of the structural body 41, a surface that is uniformly flat or planar, i.e., that lies in the plane XY, without any protuberances or depressions or recesses (except for a possible surface roughness deriving from the manufacturing process). In other words, the membrane 42 has a uniform thickness, along the axis Z, having a value t₁ comprised between approximately 2 and 50 μm, in particular between 2 and 20 μm, even more in particular between 2 and 10 μm, for example 4 μm. The extremes of the aforementioned ranges of thicknesses are included.

The pillars 36b protrude from the membrane along the axis Z in an area corresponding to the surface 58a.

The second solid body B2 further comprises a plurality of transducers 56 (one of which is illustrated in FIG. 1A). In this context, the transducer 56 may be driven for generating a deflection of the membrane 42, or else be used for detecting a deformation of the membrane 42. By way of example, without this implying any loss of generality, below there will be exclusively considered the operation of generation of deflection of the membrane, and the transducers 56 will be referred to as actuators 56. Each actuator 56 extends over, and in contact with, the membrane 42. Each actuator 56 is operatively coupled to the membrane 42. The insulating layer 58 extends over the surface 41a underneath each actuator 56. The insulating layer 58 is in particular thinner than the structural body 41, but contributes to thickening the membrane 42. Consequently, the thickness of the insulating layer 58 is taken into account in the design stage to size the value t₁.

The membrane 42 and the actuators 56 together form a transducer device, configured to transduce an electrical signal received (control signal) into a mechanical movement of the membrane and, consequently, into an acoustic wave emitted by the electroacoustic device 1. As has been said, the opposite transduction is possible, in addition or as an alternative, according to the conditions of use of the electroacoustic device 1.

In greater detail, each actuator 56 comprises a stack 60, including a respective piezoelectric region (e.g., of PZT-lead-zirconate-titanate) and a pair of driving electrodes configured to bias the piezoelectric region in order to generate a corresponding deformation of the piezoelectric region, in a per se known manner.

Each actuator 56 is surrounded (partially or completely, in respective embodiments) by a stiffening structure 113, on which the pillars 36b extend. In one embodiment, the stiffening structure 113 is formed by the same stack 60 as the actuator 56, in order to simplify the process steps. However, it is evident that the stiffening structure 113 may be made of other materials, for example semiconductor or insulating materials, or a stack including such materials. The stiffening structure 113 has a thickness, along the axis Z, comprised, for example, between 1 μm and 50 μm.

Each actuator 56 is electrically coupled, via respective conductive paths 81, 83, to the pillars 36b. Since, in the case of a piezoelectric actuator, two actuation electrodes are provided (an upper electrode and a lower electrode with respect to the PZT layer), FIG. 1A illustrates a conductive path 81, 83 for each upper electrode and lower electrode, respectively. The conductive paths 81, 83 extend in part over the membrane 4 alongside the actuator 56, until they reach and contact underneath respective pillars 36b (other implementations of electrical connection between the conductive paths 81, 83 and the PZT stack are possible, as will be clear to the person skilled in the art, for example by providing a conductive path 83 that extends underneath the PZT stack).

Via the conductive paths 81, 83 and the pillars 36b, each actuator 56 is electrically coupled to the conductive paths 32 of the third solid body B3 and, consequently, to the redistribution structure 26. In turn, the redistribution structure 26 forms an electrical connection with corresponding bumps 18, 20 of the first and second dice 2, 4, as described previously. In this way, each actuator 56 is designed to receive electrical control signals from the dice 2, 4, which cause corresponding deformations of the membrane 42 mechanically coupled to said actuators 56, with consequent generation of an acoustic wave. Further, the deformation of the membrane 42, due (for example) to an acoustic echo signal impinging thereon, causes a corresponding deformation of the actuator 56, which generates an electrical response signal, which is then sent and is received by the receiving circuit of the dice 2, 4, which may process it (and then may supply a corresponding output signal to an external processor/controller).

In one embodiment, each actuator 56 is connected both to the transmitting circuit and to the receiving circuit of the corresponding die 2, 4.

In a further embodiment, the transmitting and receiving circuits of a die 2, 4 may manage a number of transducers 56.

Further, in each die 2, 4 mechanisms for protection of the receiving circuit may be implemented during the transmission step.

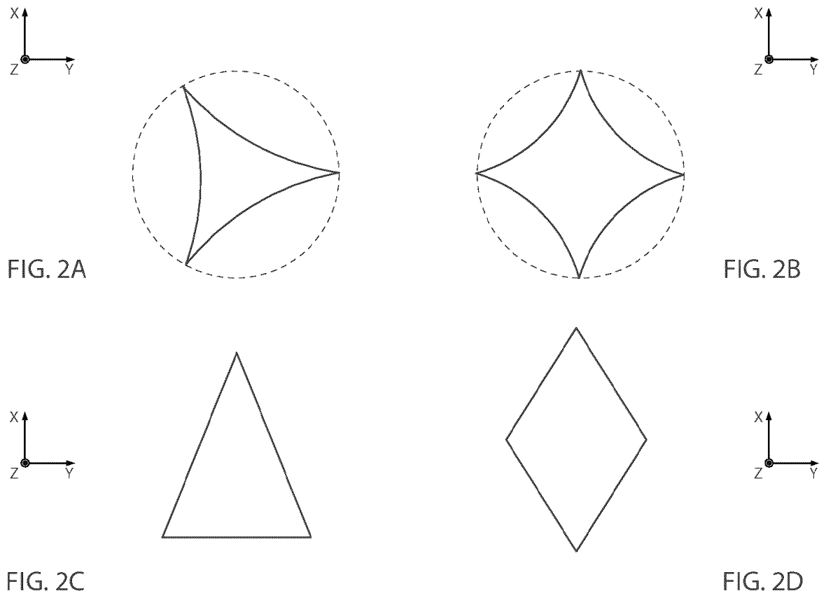

In an embodiment, each pillar 36b has a section (in the plane XY) having one of the following shapes: the shape of a hypocycloid with three cusps (FIG. 2A), also referred to as deltoid; the shape of a hypocycloid with four cusps (FIG. 2B), also referred to as astroid; the shape of a triangle (FIG. 2C), in particular, an equilateral triangle or an isosceles triangle; or a quadrangular or diamond-like shape (FIG. 2D), i.e., the shape of a quadrilateral that has two pairs of congruent consecutive sides, or else of a polygon that has four sides and that has two pairs of consecutive sides having the same size; said polygon may likewise be concave or convex.

With reference to FIGS. 2A and 2B, it may be noted that the hypocycloid is defined as the curve generated by a point of a circumference that rolls on the inner part of another circumference. When the pillars 36b have, in cross-sectional view, this shape, the dimensions of the diameter of the circumference that contains the corresponding hypocycloid are comprised between 3 μm and 100 μm. In other words, in this case, the pillars 36b have a maximum dimension, in the plane XY, comprised between the aforementioned values of diameter.

With reference to FIG. 2C, when the pillars 36b have a triangular cross-section, the dimensions of the triangle may be chosen so that it may be inscribed in a circumference having a diameter identified with reference to FIGS. 2A and 2B. By way of further example, in the case of an equilateral triangle, it is designed with a side of a value comprised between 3 μm and 50 μm; in the case of an isosceles triangle, it is designed with a base side of a value comprised between 3 μm and 50 μm, and a height of a value comprised between 3 μm and 100 μm.

With reference to FIG. 2D, when the pillars 36b have a quadrangular cross-section, the dimensions of the polygon may be chosen so that it may be inscribed in a circumference having the diameter identified with reference to FIGS. 2A and 2B. By way of further example, in the case of square cross-section of the pillars 36b, the square is designed with a side comprised between 3 μm and 50 μm; in the case of a polygonal cross-section with four sides and two pairs of consecutive sides having the same size, these sides have a size comprised between 3 μm and 70 μm.

Each pillar 36b is consequently a solid having a cross-section that is uniform throughout its extension along the axis Z, and has a shape chosen in the design stage from among the shapes listed previously (FIGS. 2A-2D).

In general, the function of the pillars 36b is to increase the stiffness of the structure 38, in particular of the membrane 42. Consequently, the greater the spatial extension of the overlapping portions (in top view in the plane XY) between the pillars 36b and the membrane 42 (with the intermediate presence of the stiffening structure 113), the greater the effect of increase in stiffness. Thus, in general the shape of the pillars 36b may be chosen such as to maximize said portions of overlapping between the pillars 36b and the stiffening structure 113 around each actuator 56.

In an embodiment, each actuator 56 is associated to just two pillars 36b (to carry the respective biasing signals of the two, upper and lower, electrodes). In this case, one of said pillars 36b may have a shape chosen from among the shapes mentioned above (FIGS. 2A-2D), and the other pillar 36b may have a generic polygonal or curvilinear shape that follows the outer profile of the respective actuator 56 in order to maximize its own portion of overlapping with the structural body 41 via the stiffening structure 113. Since each pillar 36b is configured to carry a biasing (actuation) signal of the respective actuator 56, said two pillars 36b are arranged at a distance and are electrically insulated from one another.

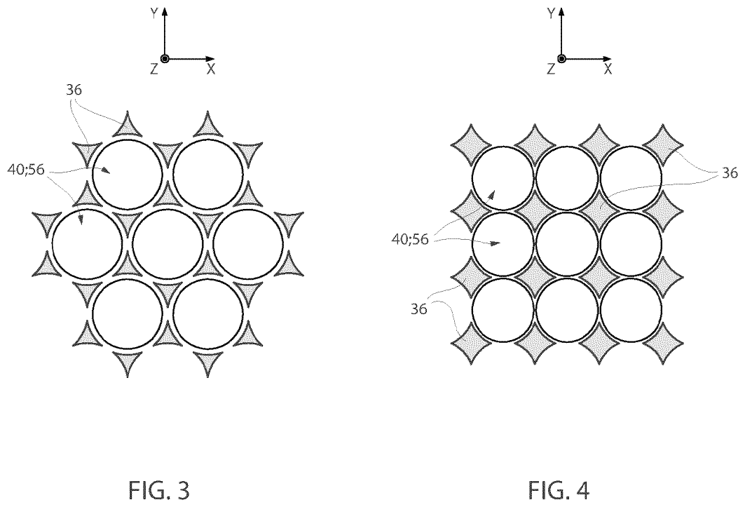

In the case where more than two pillars are present for each actuator 56, as in the examples illustrated and described in the sequel (e.g., FIG. 3 and FIG. 4), some of said pillars are not electrically active during use; i.e., they are not electrically coupled to any actuator 56, but have an exclusive function of stiffening of the membrane 42.

In one embodiment, one of the driving electrodes of the actuator 56 (e.g., the lower electrode) is common to all the actuators 56; i.e., it extends with structural and electrical continuity throughout the membrane 42, in contact with all the piezoelectric elements of all the actuators 56 (and electrically insulated from further conductive structures that are present). In this case, it is possible to envisage a single biasing path for said common electrode, said biasing path including a single pillar 36b located in any region of the membrane 42 (not necessarily in the proximity of a specific actuator 56). Alternatively, it is possible to envisage a plurality of conductive paths designed to bias the common electrode at the same time.

In a different embodiment, each actuator 56 is provided with own upper and lower electrodes that are not shared with other actuators 56. In this case, for each actuator 56 at least two respective pillars 36b are provided to carry the biasing signal to the upper and lower electrodes.

FIG. 3 illustrates, in top plan view (in the plane XY), a generic plurality of transducers 56, arranged to form a pattern defined in the design stage. In the embodiment of FIG. 3, said pattern is a honeycomb pattern; i.e., the transducers 56 are arranged along rows that extend along the axis X and that are parallel to one another along the axis Y; however, the transducers 56 are not aligned along columns parallel to the axis Y.

In a further embodiment (FIG. 4), said pattern is a matrix in which the transducers 56 are arranged to form rows along the axis X and columns along the axis Y. Each transducer 56 is located at the intersection of a respective row and a respective column of the matrix.

Even though in FIGS. 3 and 4 the pillars have a hypocycloidal cross-section with three and four cusps, respectively, said shape is not to be understood as limiting. Other shapes are possible (see FIGS. 2A-2D and in general the foregoing description). The transducers 56 are arranged in the proximity of (i.e., adjacent to) one another, to form the aforementioned pattern with interposition of the pillars 36b and of the stiffening structure 113 that separate the various membranes 42, according to the various possible embodiments described.

In an embodiment, each actuator 56 has a circular shape, in top plan view (in the plane XY). The diameter of each actuator 56 is comprised between 7 μm and 150 μm.

As may be noted, for example, from FIG. 1B, each actuator 56 is configured to deflect a respective portion 40 of the membrane 42, where each portion 40 has the same shape (e.g., circular) as the respective actuator 56, but a diameter in the plane XY greater than the respective diameter of the actuator 56. In other words, each actuator 56 is configured to actuate in deflection a respective portion 40 of the membrane 42, each membrane portion 40 being delimited on the outside by a respective stiffening structure 113. The diameter of each membrane portion 40 is, for example, comprised between 10 μm and 200 μm.

The topology of shapes proposed for the pillars 36b enables increase of the clamping area and shifting in the undesired bending modes outside the operating bandwidth.

The electroacoustic device 1 may be manufactured on the basis of the method described in what follows.

The method described refers to production of an electroacoustic device comprising a single transducer. However, it is evident that the teaching applies to the production of any plurality of transducers and respective membrane portions 40.

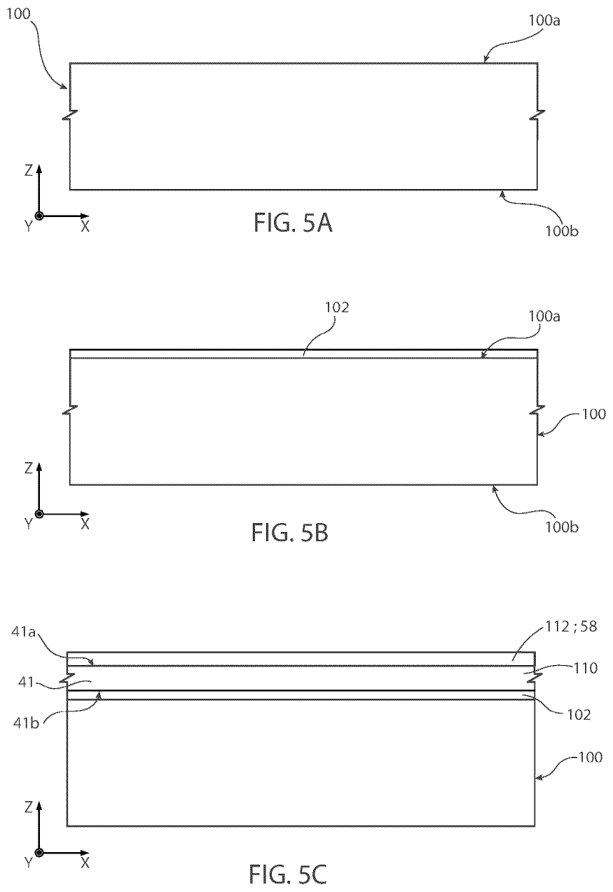

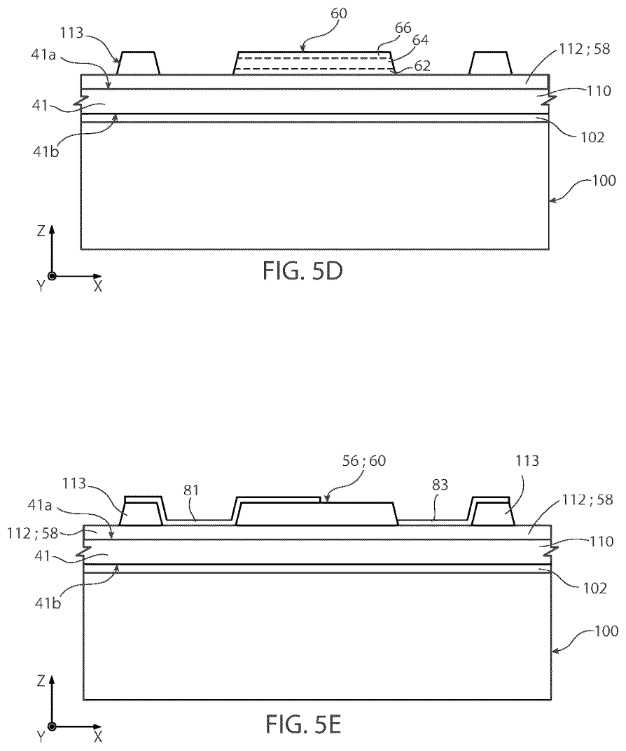

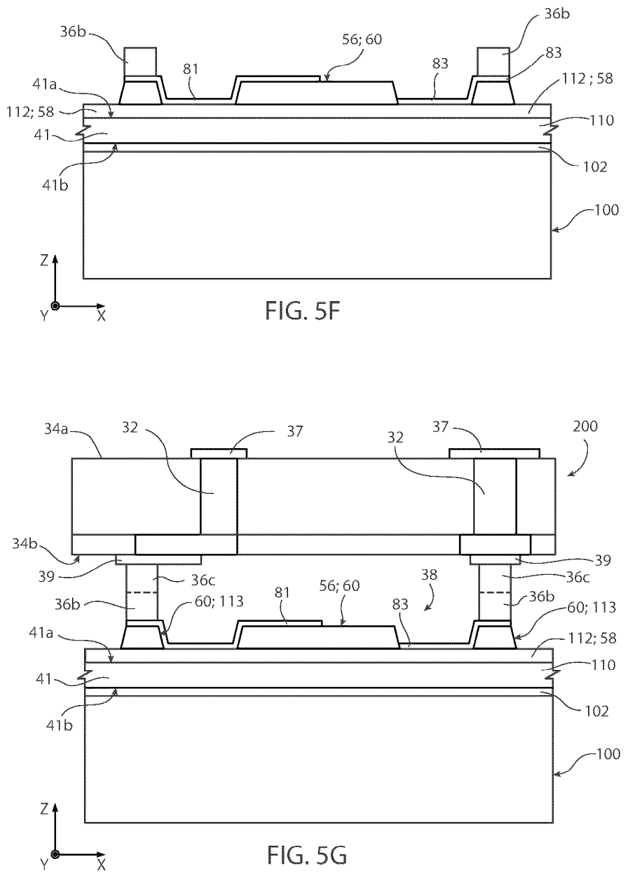

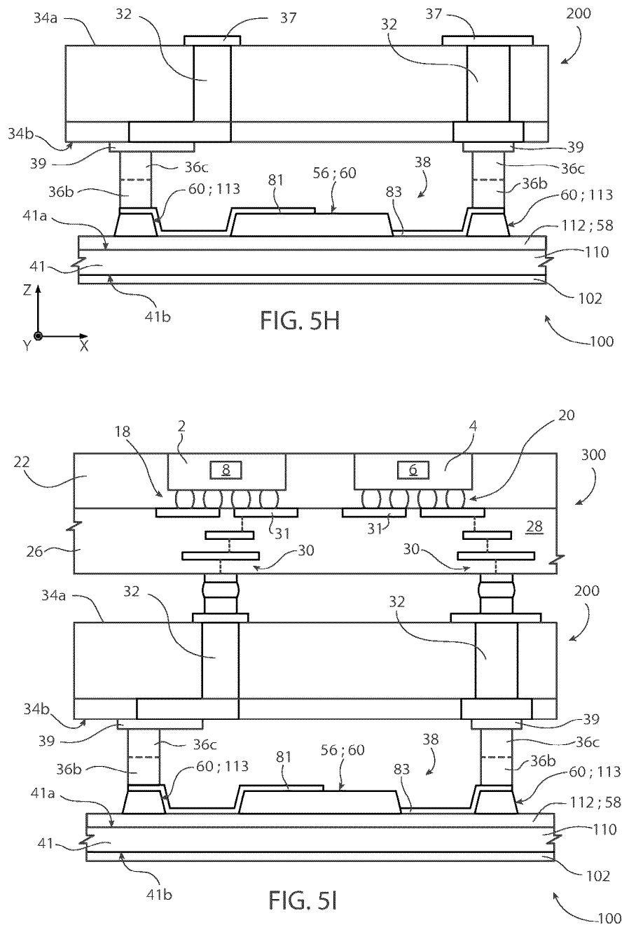

FIGS. 5A-5I are lateral sectional views in the plane XZ, in the same reference system as that of FIG. 1A.

With reference to FIG. 5A, a wafer 100 of semiconductor material, such as silicon, is provided. The wafer 100 has a front side 100a and a back side 100b, opposite to one another along the axis Z. The wafer 100 has, for example, a thickness, along the axis Z, of approximately 400 μm between the front side 100a and the back side 100b.

Then (FIG. 5B), a step is carried out of formation of an etch stop layer 102 on the front side 100a. The etch stop layer 102 is made of a material that may be selectively etched with respect to the material of the wafer 100 (for example, silicon oxide deposited or grown thermally, or else TEOS) and has a thickness comprised between approximately 0.3 μm and approximately 0.7 μm (e.g., 0.5 μm). Formation of the layer 102 is optional.

Next (FIG. 5C), a step of formation of a structural layer 110 is carried out on the front side 100a, in particular on the etch stop layer 102. The structural layer 110 is, in an embodiment, made of the same material as the wafer 100, here silicon. The structural layer 110 may be formed by epitaxial growth of silicon. The structural layer 110 has, for example, a thickness comprised between 2 μm and 50 μm, in particular comprised between 2 and 20 μm, more in particular between 2 and 10 μm, for example 4 μm. In the aforementioned ranges of values, the extremes are included.

In the case where the epitaxial growth of the layer 110 were to lead to formation of a layer 110 thicker than desired, it is possible to thin it out by a CMP (Chemical-Mechanical-Planarization) step, until a desired final thickness of the structural layer 110 is reached.

Then (FIG. 5D), formed, on the structural layer 110 is an insulating or dielectric layer 112 (which in the electroacoustic device 1 of FIG. 1A is the layer 58) made, for example, of silicon oxide, having a thickness comprised between 0.5 μm and 3 μm, in particular 1 μm.

Next, a step of formation of the actuator 56 and of the stiffening structure is carried out.

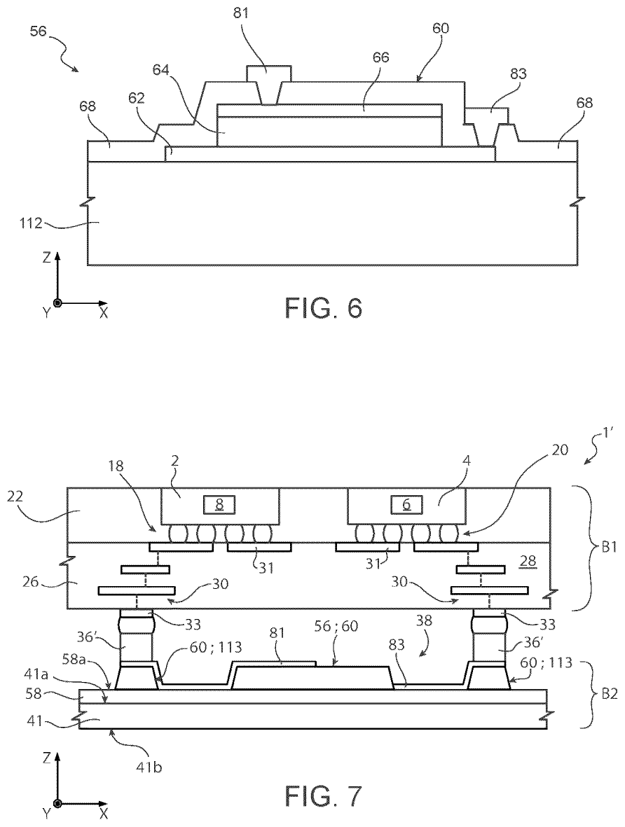

In an embodiment (exemplified in FIG. 6), the actuator 56 is of a piezoelectric type and is formed by a stack 60 comprising: a first electrode 62 of electrically conductive material, for example titanium (Ti) or platinum (Pt); a layer of piezoelectric material 64, for example, PZT (Pb, Zr, TiO₃) on the first electrode 62, in electrical contact therewith; a second electrode 66, for example of TiW (alloy of titanium and tungsten) on the piezoelectric layer 64, in electrical contact therewith; and a dielectric layer 68, for example of silicon oxide and silicon nitride laid by CVD to protect the electrodes 62, 66 and the piezoelectric layer 64.

As has been said, the stiffening structure 113 extends (in cross-sectional view) alongside the stack 60 and (in top plan view) and surrounds at least in part (completely, in the embodiment represented) the actuator 56 and the membrane 40.

The stiffening structure 113 is, in one embodiment, formed by the same stack 60 as described previously in order to optimize the manufacturing steps.

However, it is evident that the manufacturing process may envisage a stiffening structure of some other material, a stack of semiconductor and insulating material.

Then (FIG. 5E), the conductive paths 81, 83 are formed by deposition and patterning (e.g., by a photolithographic process) of a layer of metal material. The dielectric layer 68, described with reference to FIG. 5D and illustrated in FIG. 6, extends over the sides of the layer of piezoelectric material 64 and insulates it electrically from the conductive paths 81, 83, which are in electrical contact with the first and second electrodes 62, 66, respectively (and are used to carry the electrical actuation signals of the membrane and/or to receive the signal transduced in the receiving step).

Next (FIG. 5F), the pillars 36b are formed on the stiffening structure 113 and on the respective conductive paths 81, 83. The step of formation of the pillars 36b comprises depositing a layer of metal material, for example gold or copper, and carrying out steps of lithography and etching of said metal layer using an etching mask patterned so as to define the section designed for the pillars 36b (e.g., one of the sections described previously and illustrated in FIGS. 2A-2D).

As an alternative to what is represented in FIG. 5F and described, the conductive paths 81, 83 may extend alongside the pillars 36b, in lateral electrical contact with the pillars 36b, and not underneath them. In this case, the conductive paths 81, 83 may be formed in a manufacturing step different from the one illustrated.

Then (FIG. 5G), the wafer 100 is coupled, by a wafer-to-wafer bonding process, to a TSV wafer 200, i.e., a wafer having the characteristics described with reference to the third solid body B3. Coupling is obtained by the pillars 36b. Further pillars 36c may be optionally formed on the second side 34b of the TSV wafer 200. The pillars 36c have a section with any shape, for example circular or oval, or else a shape of the type illustrated in FIGS. 2A-2D.

Next (FIG. 5H), the wafer 100 is thinned out.

For this purpose, the wafer 100 is machined to remove, by a CMP step, the semiconductor material on the back side 100b, without reaching the etch stop layer 102; then, thinning is completed by chemical etching to remove completely the semiconductor material on the back side 100b until the etch stop layer 102 is reached. Since the etching chemistry selectively removes the semiconductor material but not the material of the layer 102, etching stops automatically at the layer 102. There is thus formed the membrane 42 (as well as the membrane portions 40). The first solid body B1 also comprises, in this example, the etch stop layer 102. However, it is evident that the etch stop layer 102 may be removed by wet etching.

As an alternative to what has been described, other thinning methodologies may be used (for example, a series of chemical etches without a prior CMP step; or else a CMP step in the absence of a further chemical etch; or others still).

There is thus formed the membrane 42, having the surface 41b without projections or depressions/cavities. In this context, the surface 41b may be the exposed surface of the etch stop layer 102 (if present), or else the surface of the structural layer 110 in the case where the etch stop layer 102 is removed.

Next, as illustrated in FIG. 51, the TSV wafer 200 (together with the wafer 100 coupled thereto) is physically and electrically coupled to an ASIC wafer 300 via pillars 36a; the ASIC wafer 300 includes the redistribution structure 26 and the first and second dice 2, 4 coupled together by the bumps 18, 20, as described with reference to the first solid body B1. The ASIC wafer 300 is arranged, along the axis Z, on the TSV wafer 200 (in particular, on the first surface 34a) and coupled by a wafer-to-wafer bonding or welding process.

The steps for manufacturing the ASIC wafer 300 (including the redistribution structure 26 and the dice 2, 4) need not be described herein. It may likewise be noted that both the TSV wafer 200 and the ASIC wafer 300 may be obtained in an already manufactured form.

Without this implying any loss of generality, manufacture of the ASIC wafer 300 may be obtained, as has been said with reference to FIG. 1A, by machining techniques of a FOWLP type. In this connection, the first and second dice 2, 4 may be manufactured by adopting so-called wafer-level manufacturing technologies, which enable precise manufacture, starting from a same semiconductor wafer (not illustrated), of a plurality of dice, and subsequent simulation of said dice, by dicing operations. After a possible testing step, the dice thus formed are once again mechanically coupled, via coupling with the redistribution structure 26, so as to form the ASIC wafer 300. In practice, the ASIC wafer 300 is formed by an assembly of dice fixed together, after they have been previously simulated, so as to have the shape of a semiconductor wafer (in particular, the wafer 100), in the sense that it may be arranged on, and coupled to, the TSV wafer 200, as described. In other words, the ASIC wafer 300 represents a sort of “reconstructed wafer”. Further, the dice of the ASIC wafer 300 share a single redistribution structure 26.

Simulation steps may then be carried out, in a way not illustrated in detail (e.g., using the plasma-dicing technique).

The first, second, and third solid bodies B1-B3 are thus formed, operatively coupled together, as illustrated in FIG. 1A.

A packaging step (not described) may be carried out.

FIG. 7 shows a portion of a MEMS device 1′, in particular an electroacoustic device, even more in particular an ultrasonic transducer device (PMUT), in a triaxial system of mutually orthogonal axes X, Y, Z. The view of FIG. 7 is a cross-sectional view in the plane XZ. FIG. 7 refers to a further embodiment of the present invention.

Elements in common between FIGS. 1A and 7 are designated by the same reference numbers and are not necessarily described again in detail. The electroacoustic device 1′ comprises the first solid body B1, in particular of an FOWLP type. The first solid body B1 includes the first and second dice 2, 4, which house, respectively, the first and second integrated circuits 6, 8 (e.g., ASICs of a known type). Each of the first and second integrated circuits 6, 8 comprises a respective transmitting circuit and a respective receiving circuit for transmitting/receiving respective actuation and detection signals. The transmitting circuit, as illustrated more clearly in the sequel, is configured to generate and transmit an actuation signal of an actuator or transducer of the device 1′; the receiving circuit, as illustrated more clearly in the sequel, is configured to receive and process a signal transduced by a transducer of the device 1′. In an embodiment, one between the transmitting circuit and the receiving circuit may be absent.

In each of the first and second integrated circuits 6, 8, the corresponding transmitting and receiving circuits are electrically connected to a corresponding plurality of metal bumps, designated, respectively, by 18 and 20 and also known as microbumps. Once again, the bumps 18, 20 are electrically connected to metallizations of the corresponding dice 2, 4, for example via respective electrical contact pads.

The first solid body B1 further comprises a coating region 22, which is made, for example, of an epoxy resin and englobes the first and second dice 2, 4.

The first solid body B1 further comprises the redistribution structure 26, which comprises the dielectric region 28, which houses the plurality of conductive paths 30 (illustrated schematically). The redistribution structure 26 is delimited by a first side 26a and a second side 26b, opposite to one another along the axis Z; the conductive paths 30 extend between the first and second sides, reaching the first and second sides. Present on the sides 26a, 26b are conductive pads 31 (on the side 26a) and conductive pads 33 (on the side 26b); the conductive paths 30 are electrically connected to the conductive pads 31, 33 to form a vertical-connection path (along Z, between the side 26a and the side 26b). The dielectric region 28 is made, for example, of polyimide (or else, for example, polyamide or a glass-fiber resin). The conductive paths 30 are typically made of metal material, such as copper.

The electroacoustic device 1′ further comprises, as has been said, the second solid body B2. The second solid body B2 comprises the transduction module or structure 38, electrically coupled to the redistribution structure 26 by pillars 36′.

The transduction structure 38 comprises the structural body 41 having the first surface 41a opposite, along the axis Z, to the second surface 41b, and the insulating layer 58 on the structural layer 41, which form together the membrane 42. As already noted previously in the respective embodiment, the membrane 42 has, in an area corresponding to the second surface 41b, a surface that is uniformly flat or planar, i.e., lying in the plane XY, without protuberances or depressions or recesses (except for a possible surface roughness deriving from the manufacturing process). In other words, the membrane 42 has a thickness, along the axis Z, that is uniform, having a value t₁.

The pillars 36′ protrude from the membrane 42 along the axis Z in a region corresponding to the surface 58a.

The second solid body B2 further comprises the transducers 56 (just one of which is illustrated in FIG. 7). The transducer 56 may be driven to generate a deflection of the membrane 42, or else be used for detecting a deformation of the membrane 42. By way of example, without this implying any loss of generality, there will be considered below the operation of generation of the deflection of the membrane, and the transducers 56 will be referred to as “actuators 56”. Each actuator 56 extends over, and in contact with, the membrane 42. Each actuator 56 is operatively coupled to the membrane 42. The insulating layer 58, for example, of silicon oxide, extends over the surface 41a underneath each actuator 56.

The membrane 42 and the actuators 56 together form a transducer device, configured to transduce an electrical signal received (actuation signal) into a mechanical movement of the membrane and, consequently, into an acoustic wave emitted by the electroacoustic device 1′. The opposite transduction is, as has been said, possible, in addition or as an alternative, according to the conditions of use of the electroacoustic device 1′.

In greater detail, each actuator 56 comprises the stack 60, already described with reference to FIG. 6 and illustrated therein.

Each actuator 56 is surrounded (partially or completely, in respective embodiments) by the stiffening structure 113, on which the pillars 36′ extend. The stiffening structure 113 has been described previously, and this description applies also to FIG. 7.

Each actuator 56 is electrically coupled, via respective conductive paths 81, 83, to the pillars 36′. Since in the case of a piezoelectric actuator two actuation electrodes are provided (an upper electrode and a lower electrode with respect to the PZT layer), FIG. 7 illustrates one conductive path 81, 83 for each upper electrode and lower electrode, respectively. The conductive paths 81, 83 extend in part over the membrane 42 alongside the actuator 56 until it reaches and contacts, underneath, respective pillars 36′ (other implementations of electrical connection between the conductive paths 81, 83 and the PZT stack are possible, as will be clear to the person skilled in the art, for example by providing a conductive path 83 that extends underneath the PZT stack).

Via the conductive paths 81, 83 and the pillars 36′, each actuator 56 is electrically coupled to the pads 33 and, by the latter, to the conductive paths 30 of the redistribution structure 26, which carry the signals from and to the corresponding bumps 18, 20 associated to the first and second dice 2, 4.

In an embodiment, each actuator 56 is connected both to the transmitting circuit and to the receiving circuit of the corresponding dice 2, 4. In a further embodiment, the transmitting and receiving circuits of a die 2, 4 may manage a number of transducers 56. Further, in each die 2, 4 there may be implemented mechanisms of protection of the receiving circuit, during the transmission step.

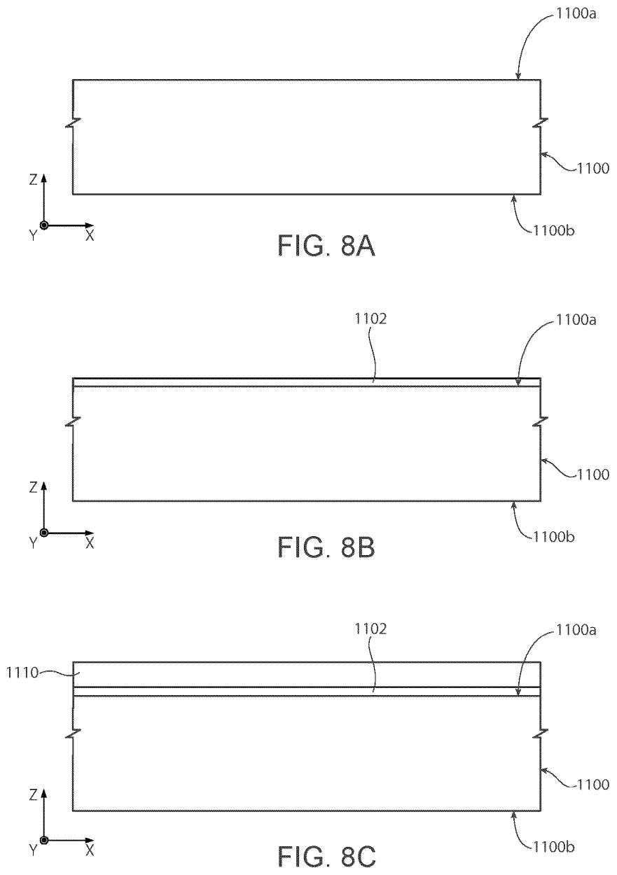

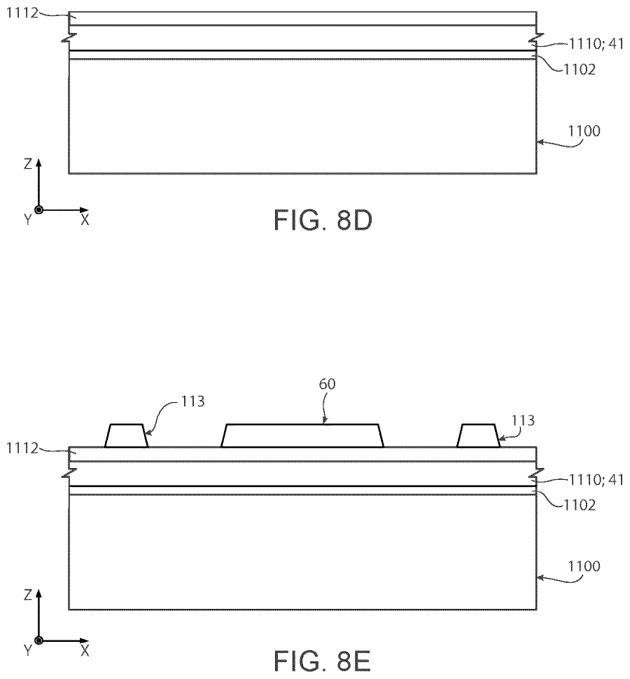

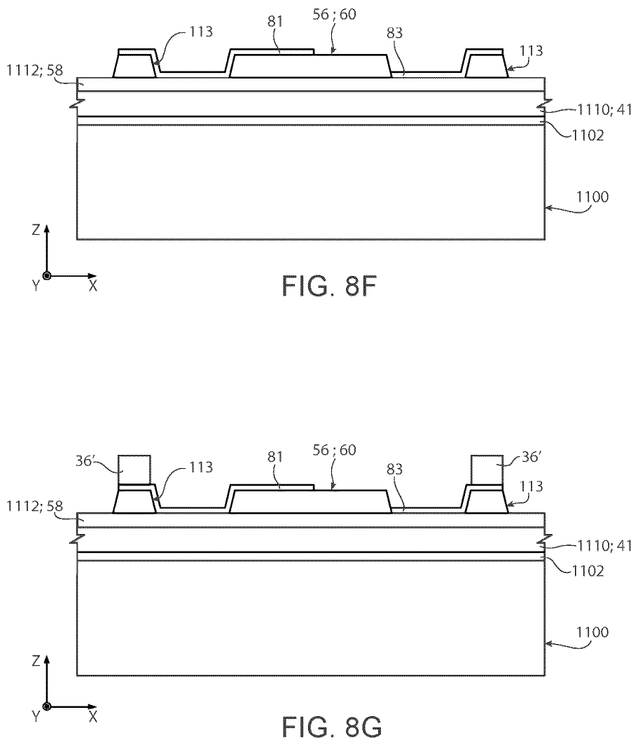

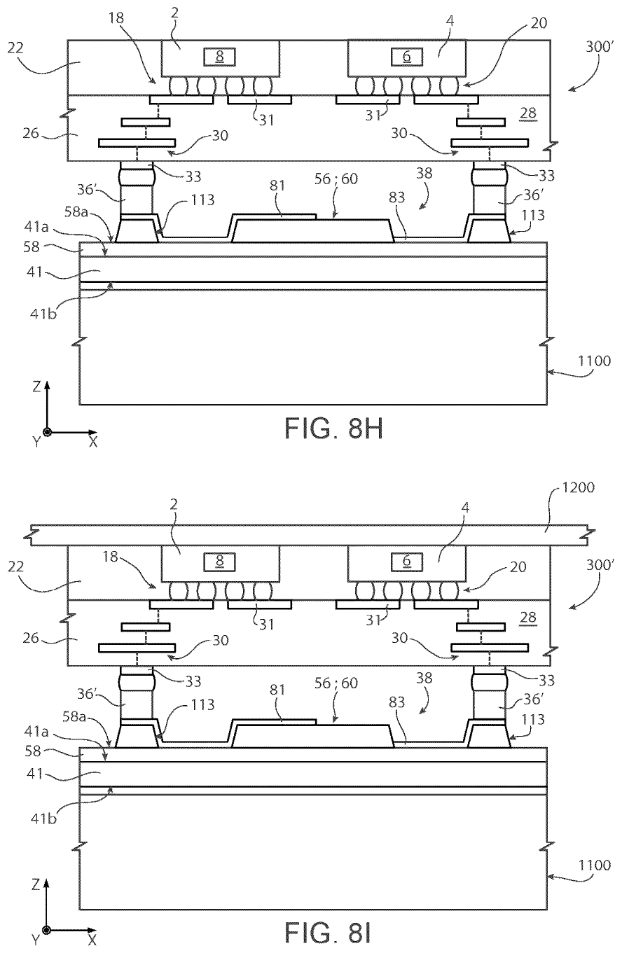

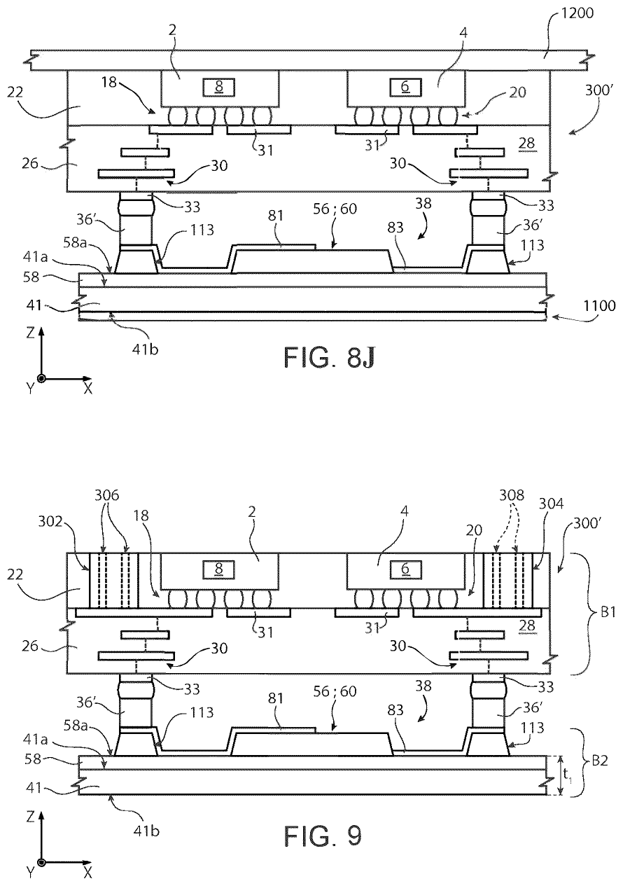

FIGS. 8A-8J illustrate steps for manufacturing the electroacoustic device 1′ of FIG. 7 in lateral sectional view in the plane XZ, in the same reference system as that of FIG. 7.

With reference to FIG. 8A, a wafer 1100 of semiconductor material, such as silicon, is provided. The wafer 1100 has a front side 1100a and a back side 1100b, opposite to one another along the axis Z. The wafer 1100 has, for example, a thickness, along the axis Z, of approximately 400 μm between the front side 100a and the back side 100b.

Then (FIG. 8B), a step is carried out of formation of an etch stop layer 1102 on the front side 1100a. The etch stop layer 1102 is made of a material that may be selectively etched with respect to the material of the wafer 1100 (for example, silicon oxide deposited or grown thermally, or else TEOS) and has a thickness comprised between approximately 0.3 μm and approximately 0.7 μm (e.g., 0.5 μm).

Next (FIG. 8C), a step is carried out of formation of a structural layer 1110 on the front side 1100a, in particular on the etch stop layer 1102. The structural layer 1110 is made, in one embodiment, of the same material as the wafer 1100, here silicon. The structural layer 1110 may be formed by epitaxial growth of silicon. The structural layer 1110 has a thickness, for example, comprised between 3 μm and 100 μm, in particular 10 μm. Then, the thickness of the structural layer 1110 is reduced by a CMP step until a final thickness of the structural layer 1110 comprised between 3 μm and 10 μm, in particular 4 μm, it reached. As an alternative, the structural layer 1110 may be grown so as to have the desired final thickness.

Next (FIG. 8D), formed on the structural layer 110 is an insulating or dielectric layer 1112 (which, will then become the layer 58 of FIG. 7) made, for example, of silicon oxide, having a thickness comprised between 0.5 μm and 3 μm, in particular 1 μm.

Then (FIG. 8E), a step is carried out of formation of the actuator 56 and of the stiffening structure 113, as already described with reference to FIG. 6.

The stiffening structure 113 is, in any embodiment, formed by the same stack 60 as described previously in order to optimize the manufacturing steps.

However, it is evident that the manufacturing process may envisage a stiffening structure of some other material, such as a stack of semiconductor and insulating material.

Next (FIG. 8F), the conductive paths 81, 83, of metal material, are formed, for example via deposition and photolithographic steps.

Then (FIG. 8G), the pillars 36′ are formed on the stiffening structure 113 and on the respective conductive paths 81, 83. The step of formation of the pillars 36′ comprises depositing a layer of metal material, for example gold or copper, and carrying out steps of lithography and etching of the metal layer using an etching mask patterned so as to define the section designed for the pillars 36′ (e.g., one of the sections described previously and illustrated in FIGS. 2A-2D).

As an alternative to what is represented in FIG. 8G, the conductive paths 81, 83 may extend alongside the pillars 36′, in lateral electrical contact with the pillars 36′, and not underneath them. In this case, the conductive paths 81, 83 may be formed in a manufacturing step different from the one illustrated.

Then (FIG. 8H), the wafer 1100 is physically and electrically coupled to a plurality of dice 300′ that house ASICs 6, 8, which have functions similar to what has already been described with reference to the ASIC wafer 300; functionally similar elements are designated by the same reference numbers and are not described any further.

Unlike what has been described with reference to FIGS. 5A-5I, in this embodiment there is not used an entire FOWLP wafer 300, but, as has been said, a plurality of dice 300′ are used arranged alongside one another, each die 300′ also being obtained using FOWLP technology.

The coupling between the wafer 1100 and the FOWLP 300′ dice is obtained via the pillars 36′. The FOWLP dice 300′ are then arranged on top, along the axis Z, of the wafer 1100 (in particular, on the front side 1100a) and coupled to the pillars 36′ by techniques per se known of welding or bonding.

Then (FIG. 81), the FOWLP dice 300′ are coupled, on the side opposite to the one facing the wafer 1100, to a supporting tape 1200. In particular, the tape 1200 has an adhesive surface, where the FOWLP dice 300′ are coupled to be supported and sustained. Since the FOWLP dice 300′ might not be perfectly coplanar with one another in at the respective surfaces coupled to the tape 1200, it is preferable to use a tape 1200 provided with a resin on the adhesive surface so that the resin may even out any possible irregularities and misalignments in the direction Z of the FOWLP dice 300′. The resin is, for example, designed to solidify when exposed to UV radiation. A technology designed for this purpose is described, for example, in “Advanced Dicing Technologies for Combination of Wafer to Wafer and Collective Die to Wafer Direct Bonding”, 2019, IEEE 69th Electronic Components and Technology Conference (ECTC), which is incorporated herein by reference in its entirety.

Then (FIG. 8J), a step of thinning of the wafer 1100 is carried out, on the back side 1100b, to remove completely the material of the wafer 1100 until the etch stop layer 1102 is reached. This thinning step is carried out in a way similar to what has been described with reference to FIG. 5H, i.e., by CMP and etching steps (alternative to one another or in sequence).

The membrane 42 is thus formed, having the surface 41b without projections or depressions/cavities. In this context, as has been said, the surface 41b may be the exposed surface of the etch stop layer 1102 (if present), or else the surface of the structural layer 1110 in the case where the etch stop layer 1102 is removed.

Singulation steps may then be carried out, in a way not illustrated (e.g., by plasma-dicing technique).

Then, the tape 1200 is removed to obtain the electroacoustic device 1′ of FIG. 7.

It is clear that modifications and variations may be made to what has been described and illustrated herein, without thereby departing from the scope of the present invention, as defined in the annexed claims.

For instance, as illustrated in FIG. 9 (based upon FIG. 7), the ASIC wafer 300 (and likewise the solid body B1), in all the embodiments described previously, may be replaced by a structure or wafer 300′ (or solid body B1′) different from a FOWLP structure. The solid body B1′ houses the actuation and detection circuits (e.g., ASICs) in a containment region 22′ of insulating material, for example SiO₂. For instance, it is possible to use a reconstructed ASIC wafer including the dice 2, 4 and further dice 302, 304 having the function of housing through vertical vias 306, 308 for transferring operating signals along the thickness (direction of the axis Z) of the wafer 300′.

The alternative embodiment of FIG. 9 applies, in a similar manner, also to the embodiment of FIG. 1A.

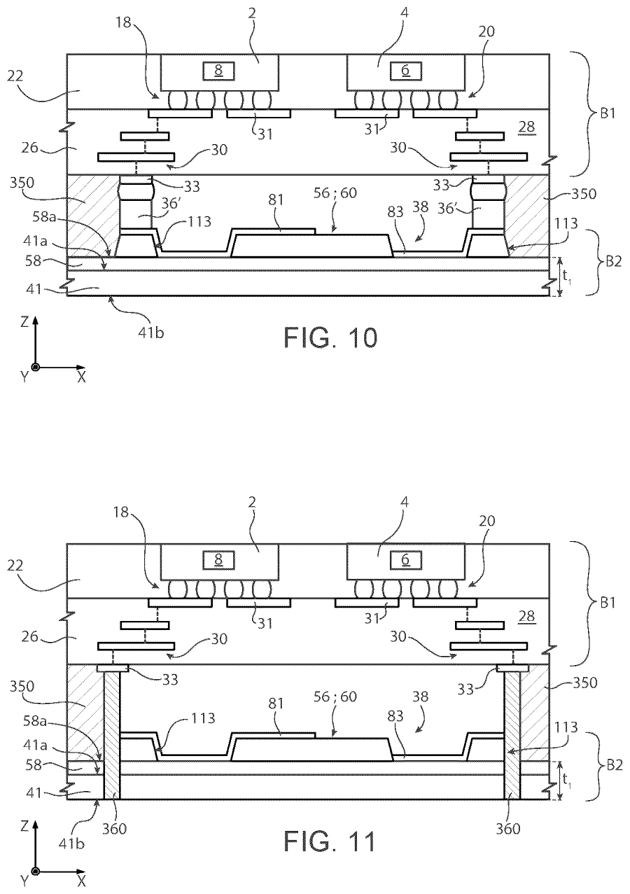

Further, as illustrated in FIG. 10 (which is itself based upon FIG. 7, but what has been described and illustrated applies in a way similar to the embodiment of FIG. 1A or FIG. 9), it is possible to reinforce the structure of the device 1′ by filling the spaces between the solid bodies B1 and B2 by insulating filler material 350, such as SiO₂. The area that houses the transducer/actuator 56 is not filled with said filler material. The solution of FIG. 10 may be applied to the embodiment of FIG. 1A by filling with the insulating filler material also the space between the solid bodies B1 and B3 (as well as between the solid bodies B2 and B3, as is illustrated in FIG. 10).

According to a further embodiment (illustrated in FIG. 11 and based upon FIG. 10), it is possible to form through trenches through the region/regions of insulating filler material 350 and fill completely said trenches with conductive material in order to form conductive through vias 360 through the solid body B2.

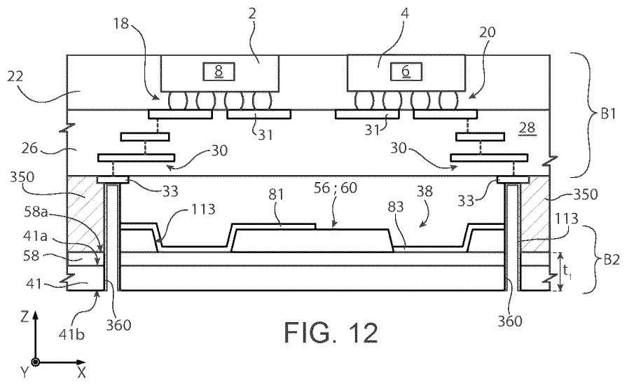

As an alternative (FIG. 12), the trenches may be metalized on their side walls and at the bottom, and not filled completely with conductive material, to form in any case conductive through vias 360. In this case, the trenches are partially hollow, and the surface 41b of the membrane 42 is uniformly planar or flat except for the regions where the partially hollow trenches are present. In these regions, in fact, the hole corresponding to the trench is present.

The conductive through vias 360, irrespective of whether the embodiment of FIG. 11 or the embodiment of FIG. 12 is considered, may be formed in addition to the pillars 36b, 36c or else, as illustrated in FIG. 11 and FIG. 12, as an alternative to the pillars 36b, 36c. In this latter case, each actuator 56 is electrically coupled, via respective conductive paths 81, 83, to the conductive through vias 360. The conductive paths 81, 83 extend until they reach and contact the conductive through vias 360. Via the conductive paths 81, 83 and the conductive through vias 360, each actuator 56 is electrically coupled to the third solid body B3 (embodiment of FIG. 1A) or else to the second solid body B2 (embodiment of FIG. 10). Irrespective of the embodiment, each actuator 56 is designed to receive electrical control signals from the dice 2, 4 through the conductive through vias 360.

According to further variants with respect to what has been described previously, each electroacoustic device may comprise a number of dice different from what is illustrated, in which case the manufacturing method is modified accordingly. The transmitting and receiving circuits may be formed in different dice; in this case, the transmitting and receiving circuits may be formed using different technologies.

In general, the actuators may be of a type different from what has been described. For instance, the actuators may implement an actuation mechanism of an electrostatic, instead of piezoelectric, type. Likewise, also the arrangement of the actuators with respect to the corresponding membranes may be different from what has been described.

Furthermore, instead of the bumps 18, 20, other conductive connection elements may be used, such as corresponding pillars. More in general, all the conductive connection elements described herein are provided merely by way of example.

Further, each pillar 36b may, in general, be a hypocycloid having a number of cusps equal to or greater than three (e.g., five).

Furthermore, the shape of each pillar 36b may be different for pillars 36b that are different from one another.

1. A method for manufacturing a microelectromechanical systems (MEMS) device, comprising:
forming a first solid body that forms a layered structure on a substrate, wherein the layered structure has a first surface that is planar throughout an extension thereof and that faces the substrate;
forming a plurality of transducer devices on a second surface of the layered structure that is opposite to the first surface in a direction;
coupling the first solid body to a supporting structure; and
completely removing the substrate to expose said first surface.

2. The method according to claim 1, wherein the layered structure forms a membrane, and wherein the plurality of transducer devices are arranged on the membrane.

3. The method according to claim 1, wherein said supporting structure is a TSV (Trough-Silicon Via) wafer.

4. The method according to claim 1, wherein forming the first solid body includes forming the supporting structure as a wafer manufactured using FOWLP (Fan-Out Wafer-Level Package) technology having a first side coupled to the first solid body and a second side, opposite to the first side in said direction, coupled to a supporting adhesive tape.

5. The method according to claim 1, wherein said supporting structure is formed to include a plurality of integrated circuit dice manufactured using FOWLP technology, each die having a first side coupled to the first solid body and a second side, opposite to the first side in said direction, coupled to a supporting adhesive tape.

6. The method according to claim 1,
wherein said supporting structure is formed to include a second solid body that includes application specific integrated circuit (ASIC) dice and a redistribution structure;
wherein the redistribution structure is formed to have a first side coupled to the first solid body and a second side, opposite to the first side in said direction, facing the ASIC dice, and wherein conductive paths extend between the first and second sides in electrical connection with the ASIC dice; and
wherein the supporting structure is further formed to include a supporting adhesive tape coupled to the second solid body in a position corresponding to said ASIC dice.

7. The method according to claim 1, further comprising forming mechanical and electrical coupling structures between the first solid body and the supporting structure.

8. The method according to claim 7, further comprising electrically coupling respective coupling structures of said plurality of coupling structures to respective transducer devices of the plurality of transducer devices.

9. The method according to claim 1, further comprising forming a stiffening structure around each transducer device of said plurality of transducer devices.

10. The method according to claim 8,
further comprising forming a stiffening structure around each transducer device; and
wherein said coupling structures are formed to have a respective cross-section, along a cutting plane orthogonal to said direction, having a shape such as to maximize overlap with the stiffening structure around the respective transducer device.

11. The method according to claim 7, wherein said mechanical and electrical coupling structures are formed to have a cross-section with a shape chosen from among the group consisting of: hypocycloidal with a number of cusps equal to or greater than three;
triangular; and quadrangular.

12. The method according to claim 4, further comprising removing the supporting adhesive tape after completely removing the substrate.

13. The method according to claim 3, further comprising, after completely removing the substrate, coupling a second solid body manufactured using FOWLP technology to the TSV wafer.

14. The method according to claim 13, wherein said second solid body is formed to comprise ASIC dice and a redistribution structure, wherein the redistribution structure has a first side coupled to the second solid body and a second side, opposite to the first side in said direction, facing the ASIC dice, and wherein conductive paths are formed to extend between the first and second sides of the redistribution structure.

15. The method of claim 1, wherein the layered structure has a thickness of a value ranging between 2 and 50 μm.

16. A microelectromechanical systems (MEMS) device, comprising:
a first solid body including signal-processing circuitry;
a second solid body including a membrane having a first side and a second side opposite to one another in a direction, the first side of the membrane facing the first solid body, the first and second solid bodies being fixed with respect to one another;
a plurality of transducer devices which extend on the first side of the membrane; and
a plurality of coupling elements which extend between the first and second solid bodies and are configured to electrically couple each transducer device to the signal-processing circuitry;
wherein said membrane has a thickness that is uniform in said direction; and
wherein the second side of the membrane is planar throughout its extension.

17. The MEMS device according to claim 16, wherein the plurality of transducer devices share a same membrane.

18. The MEMS device according to claim 16, wherein the first and second solid bodies are coupled together by a through silicon via (TSV) wafer that extends between the first and second solid bodies, and wherein the first solid body is a wafer manufactured using fan out wafer level packaging (FOWLP) technology.

19. The MEMS device according to claim 16, wherein said MEMS device is an ultrasonic transducer device.

20. The MEMS device according to claim 16, wherein said MEMS device is a piezoelectric micromachined ultrasonic transducer (PMUT).

21. The MEMS device according to claim 16, wherein the thickness of said membrane has a value ranging between 2 and 50 μm.

22. A microelectromechanical systems (MEMS) device, comprising:
a first solid body including signal-processing circuitry;
a second solid body including a membrane having a first side and a second side opposite to one another in a direction, the first side of the membrane facing the first solid body, and the first and second solid bodies being fixedly coupled together by mechanical-coupling regions;
a plurality of transducer devices that extend on the first side of the membrane; and
a plurality of electrical coupling elements which include: conductive paths in the first solid body which are electrically coupled to the signal-processing circuitry; and conductive through-vias which extend throughout the thickness of the membrane and of said mechanical-coupling regions until they reach and contact the conductive paths of the first solid body;
wherein said membrane has a thickness that is uniform in said direction; and
wherein the second side of the membrane is planar throughout its extension except for regions where said conductive through-vias are present.

23. The MEMS device according to claim 22, wherein the plurality of transducer devices share a same membrane.

24. The MEMS device according to claim 22, wherein the first and second solid bodies are coupled together by a through silicon via (TSV) wafer that extends between the first and second solid bodies, and wherein the first solid body is a wafer manufactured using fan out wafer level packaging (FOWLP) technology.

25. The MEMS device according to claim 22, wherein said MEMS device is an ultrasonic transducer device.

26. The MEMS device according to claim 22, wherein said MEMS device is a piezoelectric micromachined ultrasonic transducer (PMUT).

27. The MEMS device according to claim 22, wherein the thickness of said membrane has a value ranging between 2 and 50 μm.
